(19) United States
(12) Patent Application Publication
(10) Pub. No.: US 2024/0102741 A1
(43) Pub. Date: Mar. 28, 2024

(54) HEAT DISSIPATION STRUCTURE HAVING HEAT PIPE

(71) Applicant: AMULAIRE THERMAL TECHNOLOGY, INC., New Taipei City (TW)

(72) Inventors: CHING-MING YANG, New Taipei City (TW); CHUN-TE WU, New Taipei City (TW); TZE-YANG YEH, New Taipei City (TW)

(21) Appl. No.: 17/951,054

(22) Filed: Sep. 22, 2022

(51) Int. Cl. F28D 15/02

(52) U.S. Cl. CPC F28D 15/0233; F28D 15/0275

(57) ABSTRACT

A heat dissipation structure having a heat pipe is provided. The heat dissipation structure includes a heat dissipation base, a plurality of fins, at least one heat pipe, and at least a first heat dissipation contact material and a second heat dissipation contact material that are different from one another. The heat dissipation base has a first and a second heat dissipation surface opposite to each other. The second heat dissipation surface is connected to the fins. At least one recessed trough is concavely formed on the first heat dissipation surface. The at least one heat pipe is located in the at least one recessed trough. The first and the second heat dissipation contact material are filled in the at least one recessed trough. A melting point of the second heat dissipation contact material is smaller than a melting point of the first heat dissipation contact material.

### FIELD OF THE DISCLOSURE

The present disclosure relates to a heat dissipation structure, and more particularly to a heat dissipation structure having a heat pipe.

### BACKGROUND OF THE DISCLOSURE

With the rapid development of the technology industry, an operating speed of electronic components for a server has become faster and faster, and heat generated from the operation has also become higher and higher. In order for the electronic components to maintain operation under an acceptable temperature, the heat needs to be effectively dissipated. As such, a heat dissipation structure that is integrated with a heat pipe and a fin is conventionally installed on the electronic components, so as to achieve a better heat dissipation effect. However, gaps can easily be formed between the heat pipe and the heat dissipation structure after welding so that air thermal resistance is generated, thereby affecting heat conductivity.

### SUMMARY OF THE DISCLOSURE

In response to the above-referenced technical inadequacy, the present disclosure provides a heat dissipation structure having a heat pipe.

In one aspect, the present disclosure provides a heat dissipation structure having a heat pipe. The heat dissipation structure includes a heat dissipation base, a plurality of fins, at least one heat pipe, and at least a first heat dissipation contact material and a second heat dissipation contact material that are different from one another. The heat dissipation base has a first heat dissipation surface and a second heat dissipation surface opposite to each other. The second heat dissipation surface of the heat dissipation base is connected to the plurality of fins. At least one recessed trough is concavely formed on the first heat dissipation surface of the heat dissipation base. The at least one heat pipe is located in the at least one recessed trough. The first heat dissipation contact material and the second heat dissipation contact material are filled in the at least one recessed trough. A melting point of the second heat dissipation contact material is smaller than a melting point of the first heat dissipation contact material, so that the second heat dissipation contact material is able to liquefy and fill into a plurality of gaps formed between the first heat dissipation contact material and the at least one heat pipe in the at least one recessed trough.

In certain embodiments, the first heat dissipation contact material is a metal welding material that contains bismuth or tin.

In certain embodiments, the second heat dissipation contact material is a phase-change thermal interface material.

In certain embodiments, the phase-change thermal interface material is a paraffin material.

In certain embodiments, the first heat dissipation contact material and the second heat dissipation contact material are two thermally conductive polymers that have different melting points.

In certain embodiments, a first surface bonding layer is formed on a surface of the at least one recessed trough by a surface treatment process, and a second surface bonding layer is formed on a surface of the at least one heat pipe by a surface treatment process.

In certain embodiments, the at least one heat pipe is a flat-plate type heat pipe.

In certain embodiments, a metal cover is disposed on the first heat dissipation surface of the heat dissipation base, and the metal cover is connected to the at least one heat pipe.

Therefore, in the heat dissipation structure having the heat pipe provided by the present disclosure, by virtue of “a heat dissipation base,” “a plurality of fins,” “at least one heat pipe,” “at least a first heat dissipation contact material and a second heat dissipation contact material that are different from one another,” “the heat dissipation base having a first heat dissipation surface and a second heat dissipation surface opposite to each other, the second heat dissipation surface being connected to the plurality of fins, and at least one recessed trough being concavely formed on the first heat dissipation surface,” “the at least one heat pipe being located in the at least one recessed trough,” “the first heat dissipation contact material and the second heat dissipation contact material being filled in the at least one recessed trough,” and “a melting point of the second heat dissipation contact material being smaller than a melting point of the first heat dissipation contact material, so that the second heat dissipation contact material is able to liquefy and fill into a plurality of gaps formed between the first heat dissipation contact material and the at least one heat pipe in the at least one recessed trough,” air thermal resistance can be effectively reduced, and heat conductivity can be increased.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a side view showing manufacturing of a heat dissipation structure having a heat pipe according to a first embodiment of the present disclosure;

FIG. 1B is a side view of the heat dissipation structure having the heat pipe according to the first embodiment of the present disclosure;

FIG. 2 is a side view showing manufacturing of a heat dissipation structure having a heat pipe according to a second embodiment of the present disclosure;

FIG. 3 is a side view showing manufacturing of a heat dissipation structure having a heat pipe according to a third embodiment of the present disclosure;

FIG. 4 is a side view showing manufacturing of a heat dissipation structure having a heat pipe according to a fourth embodiment of the present disclosure; and

FIG. 5 is a side view of the heat dissipation structure having the heat pipe according to a fifth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

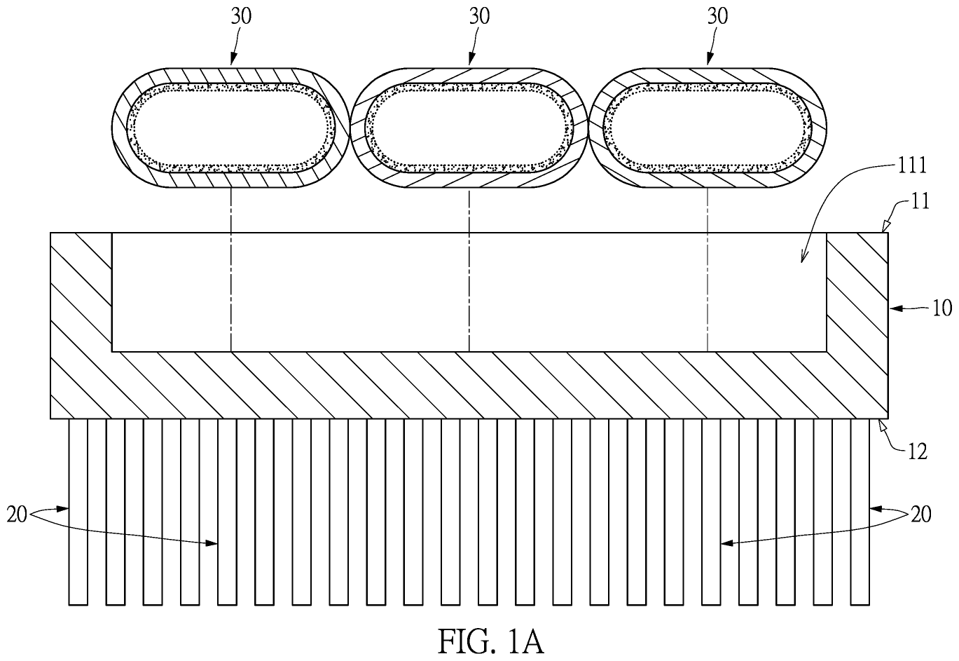

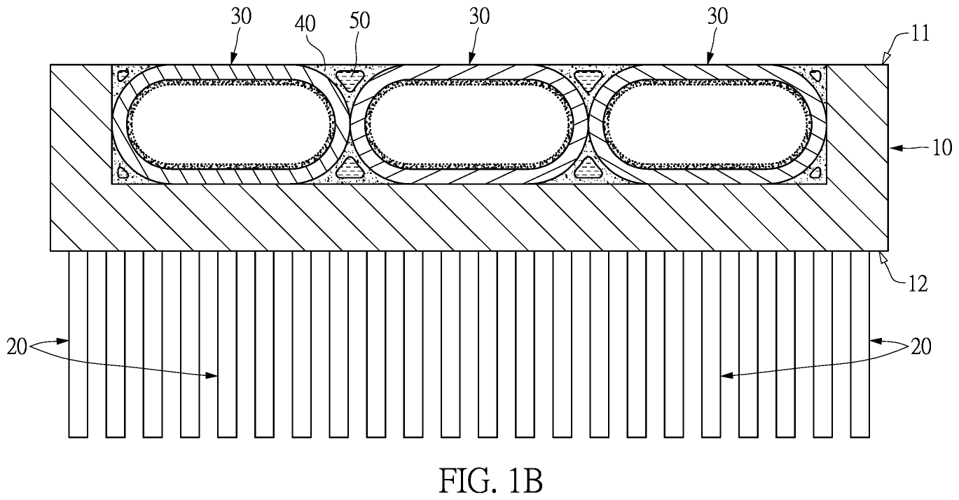

Referring to FIG. 1A and FIG. 1B, a heat dissipation structure having a heat pipe is provided in one embodiment of the present disclosure. The heat dissipation structure having the heat pipe is used for contacting electronic components of a server. As shown in FIG. 1A and FIG. 1B, the heat dissipation structure provided in the embodiment of the present disclosure includes a heat dissipation base 10, a plurality of fins 20, at least one heat pipe 30, and at least a first heat dissipation contact material 40 and a second heat dissipation contact material 50 that are different from one another.

In the present embodiment, the heat dissipation base 10 can be made of a material with high thermal conductivity, such as copper, copper alloy, aluminum and aluminum alloy. The heat dissipation base 10 has a first heat dissipation surface 11 and a second heat dissipation surface 12 opposite to each other. The second heat dissipation surface 12 of the heat dissipation base 10 is connected to the plurality of fins 20. The plurality of fins 20 and the heat dissipation base 10 can be integrally connected to one another by way of metal injection molding (MIM). That is, the plurality of fins 20 and the heat dissipation base 10 are integrally formed, thereby having a material continuity.

In the present embodiment, the first heat dissipation surface 11 of the heat dissipation base 10 has at least one recessed trough 111, and multiple ones of the heat pipe 30 are located in the recessed trough 111. Moreover, the first heat dissipation contact material 40 and the second heat dissipation contact material 50 are filled in the recessed trough 111. A melting point of the second heat dissipation contact material 50 is smaller than a melting point of the first heat dissipation contact material 40, so that the second heat dissipation contact material 50 is able to liquefy and fill into gaps formed between the first heat dissipation contact material 40 and the heat pipes 30 in the recessed trough 111. More specifically, the first heat dissipation contact material 40 can be, for example, a metal welding material including bismuth or tin (e.g., a metal welding paste). During heating of a vacuum welding stove, since a portion of the metal welding paste can be easily sucked out of the recessed trough 111 by vacuum or be pushed out of the recessed trough 111 by a gas generated from the metal welding paste, or air thermal resistance can be generated by the gaps formed between the heat pipes 30 and the recessed trough 111 due to a low solid content of the metal welding paste, the second heat dissipation contact material 50 has a melting point smaller than that of the first heat dissipation contact material 40, so as to liquefy and fill into the gaps formed between the first heat dissipation contact material 40 and the heat pipes 30 in the recessed trough 111. In this way, the air thermal resistance can be prevented from affecting heat conductivity. More specifically, the second heat dissipation contact material 50 can be a phase-change thermal interface material (e.g., a paraffin material). The paraffin material may liquefy when a temperature reaches the melting point, and may return to a solid state when the temperature is decreased.

In the present embodiment, the first heat dissipation contact material 40 and the second heat dissipation contact material 50 can be two thermal conductive polymers with different melting points. The first heat dissipation contact material 40 can be an epoxy resin that contains thermally conductive particles. The second heat dissipation contact material 50 can be polyethylene glycol with a molecular weight of 1000 (abbreviated as PEG1000). In addition, the second heat dissipation contact material 50 can be an air curing gel (anaerobic gel) or a light curing gel.

### Second Embodiment

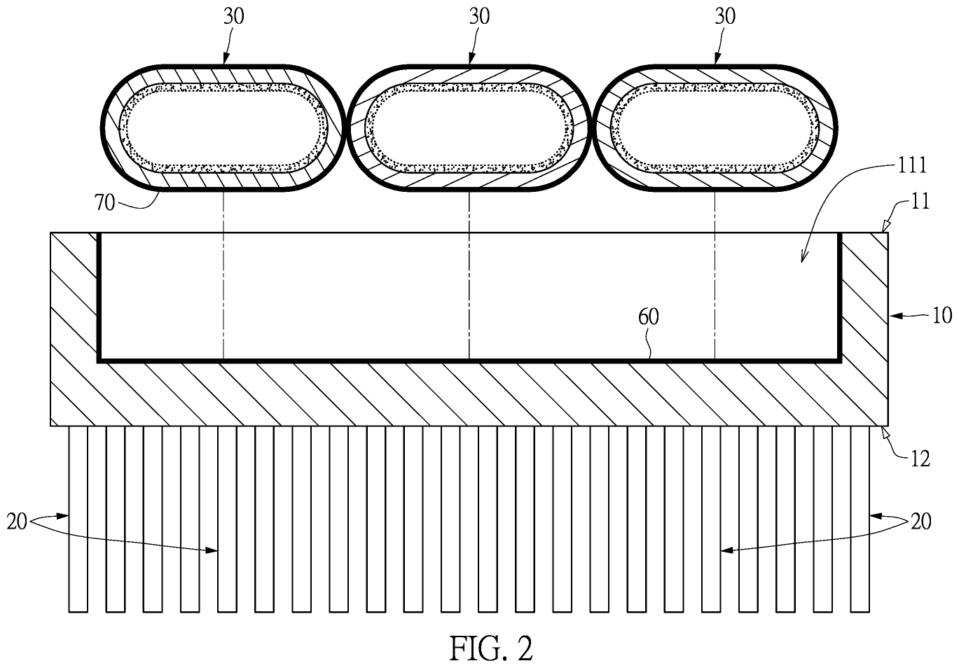

Reference is made to FIG. 2, which shows a second embodiment of the present disclosure. This embodiment is substantially the same as the first embodiment, and differences therebetween are described as follows.

In the present embodiment, a first surface bonding layer 60 is formed on a surface of the recessed trough 111 of the heat dissipation base 10 by a surface treatment process. The first surface bonding layer 60 can be a surface coating layer or a surface blasting layer. A second surface bonding layer 70 can also be formed on a surface of the heat pipe 30 by a surface treatment process. The first surface bonding layer 60 and the second surface bonding layer 70 can be used to enhance connectivity.

### Third Embodiment

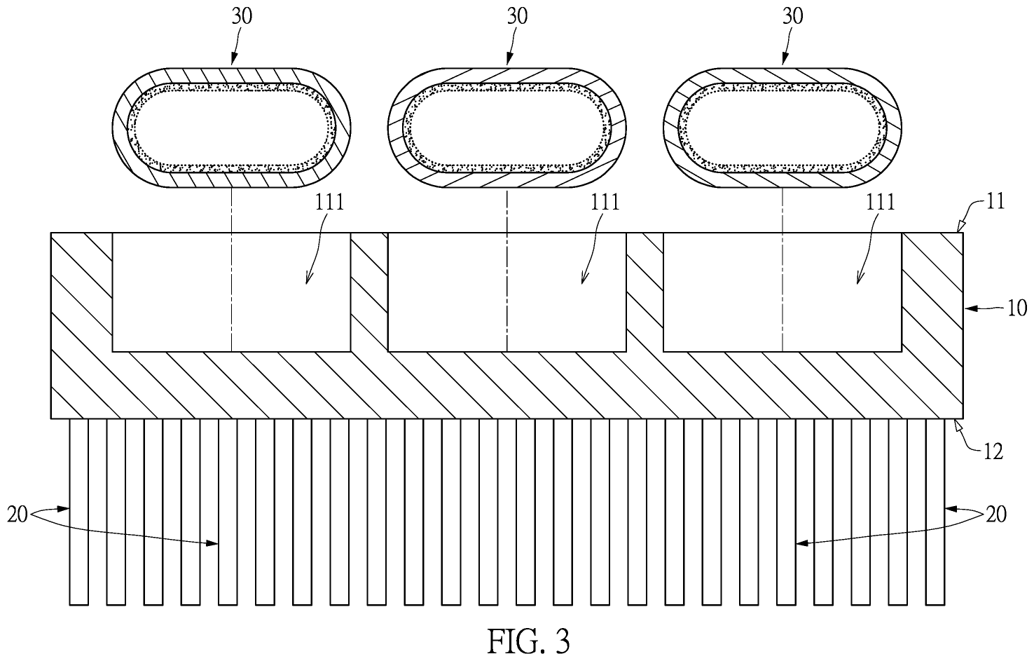

Reference is made to FIG. 3, which shows a third embodiment of the present disclosure. This embodiment is substantially the same as the first embodiment, and differences therebetween are described as follows.

In the present embodiment, multiple ones of the recessed troughs 111 are concavely formed on the first heat dissipation surface 11 of the heat dissipation base 10, and the heat pipes 30 are located in the recessed troughs 111, respectively.

### Fourth Embodiment

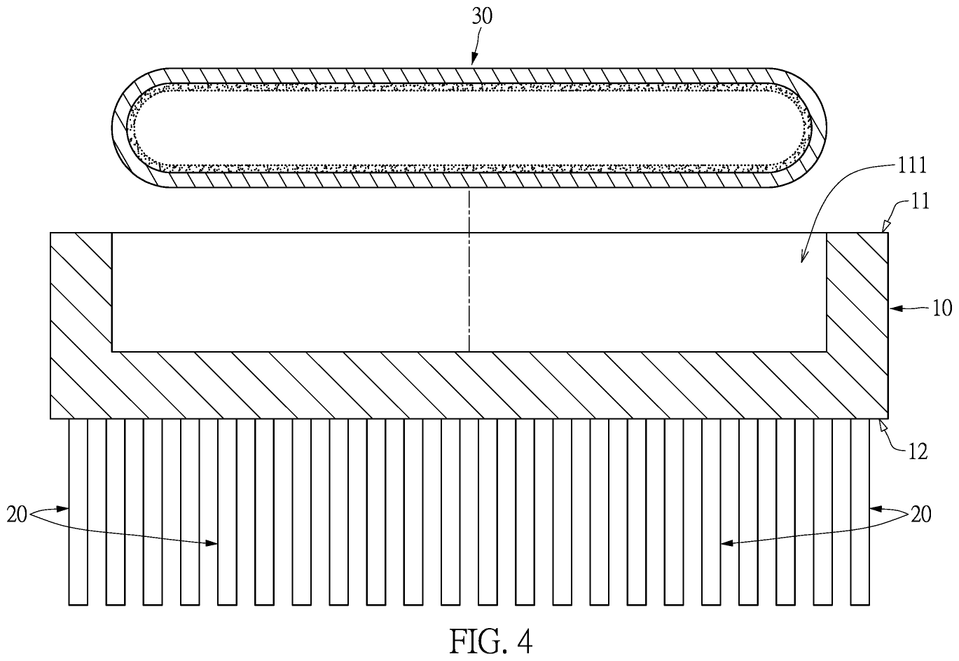

Reference is made to FIG. 4, which shows a fourth embodiment of the present disclosure. This embodiment is substantially the same as the first embodiment, and differences therebetween are described as follows.

In the present embodiment, the heat pipe 30 is a flat-plate type heat pipe, which can also be referred to as a vapor chamber.

### Fifth Embodiment

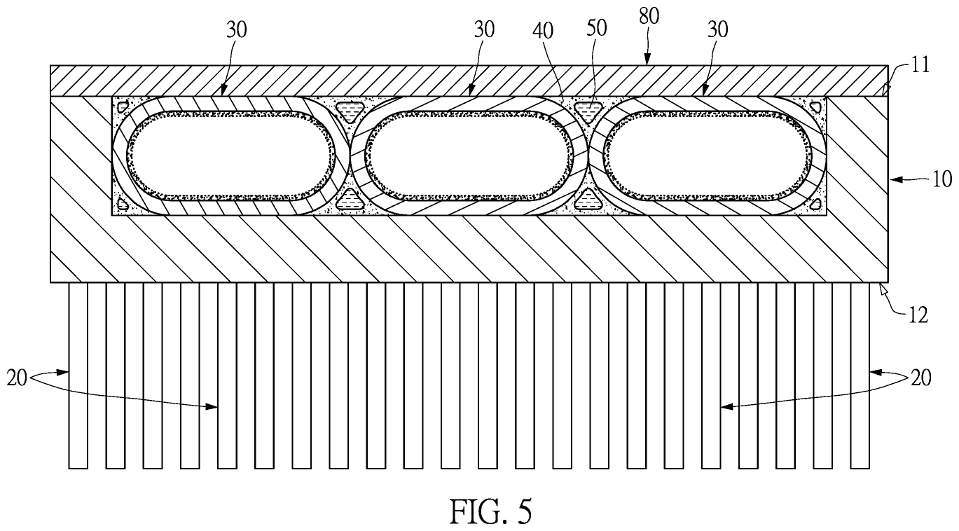

Reference is made to FIG. 5, which shows a fifth embodiment of the present disclosure. This embodiment is substantially the same as the first embodiment, and differences therebetween are described as follows.

In the present embodiment, a metal cover 80 is covered on the first heat dissipation surface 11 of the heat dissipation base 10, and the metal cover 80 is connected to the heat pipes 30. Accordingly, the heat pipes 30 indirectly contact a heat source through the metal cover 80.

### Beneficial Effects of the Embodiments

In conclusion, in the heat dissipation structure having the heat pipe provided by the present disclosure, by virtue of “a heat dissipation base,” “a plurality of fins,” “at least one heat pipe,” “at least a first heat dissipation contact material and a second heat dissipation contact material that are different from one another,” “the heat dissipation base having a first heat dissipation surface and a second heat dissipation surface opposite to each other, the second heat dissipation surface being connected to the plurality of fins, and at least one recessed trough being concavely formed on the first heat dissipation surface,” “the at least one heat pipe being located in the at least one recessed trough,” “the first heat dissipation contact material and the second heat dissipation contact material being filled in the at least one recessed trough,” and “a melting point of the second heat dissipation contact material being smaller than a melting point of the first heat dissipation contact material, so that the second heat dissipation contact material is able to liquefy and fill into a plurality of gaps formed between the first heat dissipation contact material and the at least one heat pipe in the at least one recessed trough,” air thermal resistance can be effectively reduced, and heat conductivity can be increased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat dissipation structure, comprising: a heat dissipation base, a plurality of fins, at least one heat pipe, and at least a first heat dissipation contact material and a second heat dissipation contact material that are different from one another; wherein the heat dissipation base has a first heat dissipation surface and a second heat dissipation surface opposite to each other, the second heat dissipation surface of the heat dissipation base is connected to the plurality of fins, and at least one recessed trough is concavely formed on the first heat dissipation surface of the heat dissipation base; wherein the at least one heat pipe is located in the at least one recessed trough, and the first heat dissipation contact material and the second heat dissipation contact material are filled in the at least one recessed trough; wherein a melting point of the second heat dissipation contact material is smaller than a melting point of the first heat dissipation contact material, so that the second heat dissipation contact material is able to liquefy and fill into a plurality of gaps formed between the first heat dissipation contact material and the at least one heat pipe in the at least one recessed trough.

2. The heat dissipation structure according to claim 1, wherein the first heat dissipation contact material is a metal welding material that contains bismuth or tin.

3. The heat dissipation structure according to claim 2, wherein the second heat dissipation contact material is a phase-change thermal interface material.

4. The heat dissipation structure according to claim 3, wherein the phase-change thermal interface material is a paraffin material.

5. The heat dissipation structure according to claim 1, wherein the first heat dissipation contact material and the second heat dissipation contact material are two thermally conductive polymers that have different melting points.

6. The heat dissipation structure according to claim 1, wherein a first surface bonding layer is formed on a surface of the at least one recessed trough by a surface treatment process, and a second surface bonding layer is formed on a surface of the at least one heat pipe by a surface treatment process.

7. The heat dissipation structure according to claim 1, wherein the at least one heat pipe is a flat plate heat pipe.

8. The heat dissipation structure according to claim 1, wherein a metal cover is disposed on the first heat dissipation surface of the heat dissipation base, and the metal cover is connected to the at least one heat pipe.
